(19) United States
(12) Patent Application Publication
(10) Pub. No.: US 2025/0244434 A1
(43) Pub. Date: Jul. 31, 2025

(54) ACTIVE EYE OPEN MONITOR CALIBRATION APPARATUS AND METHOD FOR ACTIVE EYE OPEN MONITOR CALIBRATION

(71) Applicant: NOVATEK MICROELECTRONICS CORP., HSINCHU (TW)

(72) Inventors: KA-WAI TANG, HSINCHU CITY (TW); HAO-TING CHU, HSINCHU CITY (TW)

(21) Appl. No.: 18/425,132

(22) Filed: Jan. 29, 2024

(51) Int. Cl. G01R 35/00

(52) U.S. Cl. CPC G01R 35/007

(57) ABSTRACT

An active eye open monitor calibration apparatus and method for active eye open monitor calibration are provided. A reference clock signal and an eye open monitor clock signal are received and a calibration selecting signal is used to control whether the reference clock signal samples the eye open monitor clock signal. An indicator signal is output and received by a phase indicating determination circuit for performing a calibration flow and accordingly calculating a phase offset signal. The eye open monitor clock is corrected based on the phase offset signal, such that a calibrated eye open monitor clock signal is synchronously in phase with the reference clock signal. By employing the proposed eye open monitor calibration apparatus and method thereof, the invention is effective in achieving phase synchronization for an eye open monitor clock signal in related to its reference clock signal, solving the phase mismatch in the related arts.

### BACKGROUND OF THE INVENTION

### Field of the Invention

The present invention is related to an eye open monitor clock signal calibrating technology. More particularly, the present invention is directed to an active eye open monitor calibration apparatus and a method for active eye open monitor calibration, in which a calibration flow is performed such that a calibrated eye open monitor clock signal is synchronously in phase with its reference clock signal.

### Description of the Related Arts

As known, an eye diagram is an important measurement for binary data transmission systems. For instance, two types of noises that can impact the performance of the data transmission system may comprise amplitude noise ad timing jitter. And an eye diagram is known for being able to provide more information on both, especially the time jitter and also measures the extinction ratio. A traditional eye diagram measurement usually involves using a digital oscilloscope and thus requires collecting a great amount of data, which is time-consuming. Thus, it is not suitable for real-time processing. A current modified methodology using digital signal processing (DSP) is thus provided so as to improve the eye diagram measurement.

Since the eye diagram or pattern is an effective tool to provide a visual examination of the severity of the inter-symbol interference (ISI), sensitivity to timing errors, and the noise margin, and the eye-pattern generation is straightforward to provide a great deal of information, an eye open monitor (EOM) is a common detection module used in a high speed data transmission system for examining the signal quality. And it allows a real-time monitoring of the input signal quality at a clock and data recovery (CDR) input terminal. Please refer to FIG. 1, which shows a schematic diagram of a conventional eye open monitor (EOM) architecture which is applied to a de-serializer circuit in the related art. The input signal RX IN is processed with a continuous time linear equalizer (CTLE) 10 followed by a plurality of sampling clock signals CLK_0, CLK_90, CLK_180, CLK_270, D flip-flop circuits 20, 22, 24, 26 as well as a demultiplexer (DMX) 30 for data transmission. For data obtained from transmission, eye quality of an eye pattern of the data usually needs to be measured to obtain the performance of the data transmission system. Currently, the eye pattern measurement directly outputs scan data, which is acquired from sampling by using multiple different clock signals, for instance, CLK_0, CLK_90, CLK_180, CLK_270, and the eye quality of the received data can be then obtained accordingly. By applying the eye open monitor (EOM) circuit 40 as a data sampler with adjustable threshold VTH and sampling clock phase, the eye open monitor (EOM) circuit 40 is operable to examine the signal quality of the input signal RX IN in the CDR data transmission system. As known, the sampling clock phase is generally assembled by a phase interpolator (PI) as shown in FIG. 1. FIG. 2 shows the plurality of different clock signals having various phase, for example, CLK_0, CLK_90, CLK_180, CLK_270, and the EOM clock CLK_EOM having the extracted same phase as the CLK_0 (illustrated as CLK_EOM@0) according to the FIG. 1 architecture. However, it draws our attention that, for power reduction purpose, the EOM clock CLK_EOM, for instance, the CLK_EOM@0 in FIG. 2, would be designed such that its phase delay 221 is not matched with the other sampler clock. Such an extra phase delay, mainly contributed by the phase interpolator (PI), usually results in difficulties in data synchronization in the de-serializer circuit. In addition, it also generates uncertainty for EOM phase control, as the mismatch might vary with the variation 223 due to PVT (Process, Voltage and Temperature) issue as well. As a result, it is evident that the phase delay and variation of the EOM clock CLK_EOM apparently fails to satisfy the in-phase requirement, which leads to significant synchronization data errors in the related arts.

As such, in order to ensure that the EOM clock CLK_EOM is able to run synchronously in related to its reference sampling clock, several methods have been discussed these days in the current technology and yet, challenges remain. Further improvements and alternative methodologies in the field are still to be expected. As a result, it, in view of all, should be apparent and obvious that there is indeed an urgent need for the professionals in the field for a novel and inventive eye open monitor (EOM) apparatus to be developed, so as to solve the above-mentioned issues, and to prevent the data errors in the synchronization obtained from eye pattern measurement and clock signals.

### SUMMARY OF THE INVENTION

In order to overcome the above-mentioned disadvantages, one major objective in accordance with the present invention is to provide a novel and active eye open monitor calibration apparatus and a method for active eye open monitor calibration.

By employing the proposed eye open monitor calibration apparatus, an active in-phase result of the EOM clock CLK_EOM in related to its reference clock signal (for instance, however, not limited to CLK_0, CLK_90, CLK_180, CLK_270) can be achieved. The present invention is aimed to prevent phase mismatch issues occurring in the related arts and to suppress data errors in the synchronization of sampling clock signals applied in an eye pattern measurement circuit. As a result, the signal quality of an input signal in a clock and data recovery (CDR) data transmission system can be accurately measured and evaluated.

The disclosed active eye open monitor calibration apparatus and the disclosed method for active eye open monitor calibration are applicable to a de-serializer circuit in a CDR data transmission device, for example. However, the present invention is certainly not limited thereto. The proposed active eye open monitor calibration apparatus and method for active eye open monitor calibration as provided in the present invention may also be applied to other circuit configurations of various CDR data transmission devices. Many alternatives and modifications will be apparent to those skilled in the art, once informed by the present disclosure.

According to one embodiment of the present invention, an active eye open monitor calibration apparatus is provided. The proposed active eye open monitor calibration apparatus includes a phase control circuit, a phase indicating determination circuit and a phase correcting circuit. The phase control circuit is adapted to receive a reference clock signal and an eye open monitor clock signal, and a calibration selecting signal is input to the phase control circuit for controlling whether the reference clock signal samples the eye open monitor clock signal, or the eye open monitor clock signal samples the reference clock signal. And the phase control circuit accordingly outputs an indicator signal.

The phase indicating determination circuit is electrically connected with the phase control circuit and receiving the indicator signal, such that the phase indicating determination circuit performs a calibration flow according to the indicator signal so as to calculate and output a phase offset signal.

The phase correcting circuit is disposed electrically connecting with the phase indicating determination circuit and receiving the phase offset signal, such that the phase correcting circuit modulates the eye open monitor clock signal based on the phase offset signal. As a result, it is obtained that a calibrated eye open monitor clock signal is synchronously in phase with the reference clock signal.

In specific, according to the embodiment of the present invention, when the calibration selecting signal is at a low voltage level, the eye open monitor clock signal is operable to sample the reference clock signal. As this time, a phase control signal increases in order as the indicator signal is kept logically low. And when the indicator signal turns logically high and is retained stably high, a first phase in related to the phase control signal is recorded.

After that, the indicator signal will be reset to logically low, and the calibration selecting signal is switched to a high voltage level such that the reference clock signal and the eye open monitor clock signal are switched. At such point of time, it is, on the other hand, the reference clock signal sampling the eye open monitor clock signal, and the phase control signal decreases in order as the indicator signal is kept logically low. When the indicator signal, once again, turns logically high and is retained stably high, a second phase in related to the phase control signal will be recorded.

Consequently, a final phase is calculated as an average phase of the first phase and the second phase and output as the phase offset signal for the phase correcting circuit to receive and to correct the eye open monitor clock signal based on the phase offset signal. As a result, it is believed that a calibrated eye open monitor clock signal and the reference clock signal are synchronously in phase.

In another aspect, the present invention is also aimed to provide a method for active eye open monitor calibration, and the disclosed method for active eye open monitor calibration includes a plurality of following steps:
(a) providing a calibration selecting signal so as to control whether a reference clock signal is sampling an eye open monitor clock signal, and outputting an indicator signal;
(b) performing a calibration flow according to the indicator signal and outputting a phase offset signal; and
(c) correcting the eye open monitor clock signal based on the phase offset signal, such that a calibrated eye open monitor clock signal is synchronously in phase with the reference clock signal.

In one embodiment, the disclosed reference clock signal can be operable to have an initial sampling clock phase of 0, 90, 180 or 270 degrees, for instance. And the reference clock signal and the eye open monitor clock signal can be received by a data selector circuit, triggered by the calibration selecting signal. Preferably, the data selector circuit may be composed of at least one multiplexer which is controlled and triggered by the calibration selecting signal.

In addition, a register circuit can be further disposed and electrically connected to the data selector circuit, such that a data input and a clock input of the register circuit are determined by the calibration selecting signal to switch between the reference clock signal and the eye open monitor clock signal for the reference clock signal sampling the eye open monitor clock signal, or the eye open monitor clock signal sampling the reference clock signal. According to one embodiment of the present invention, the register circuit for example, can be a D flip-flop (DFF) circuit, and the DFF circuit outputs the indicator signal for the phase indicating determination circuit to receive and to perform the calibration flow based on the indicator signal as a flag signal.

Therefore, by employing the present invention, it is believed that phase synchronization for the eye open monitor clock signal in related to its reference clock signal can be greatly achieved.

The applicants of the invention have proposed the disclosed active eye open monitor calibration apparatus and the disclosed method for active eye open monitor calibration as above mentioned and the disclosed active eye open monitor calibration apparatus and method for active eye open monitor calibration can be applied to a clock and data recovery data transmission device. Nevertheless, by adopting the proposed technical contents of the invention, it is to be understood that, the above eye pattern measurement scheme architecture may be applied to any circuit system that needs to measure the eye quality of data signals, and is not limited to being applied in the above CDR system for achieving phase synchronization and avoiding phase mismatch. Thereby, it is believed that the present invention achieves to successfully solves the problems of related arts and performs as being highly competitive and able to be widely utilized in any related industries.

To sum up, it has been proved and verified that the present invention is sophisticatedly designed, and the whole new calibrating techniques can be effectively employed in the data communication system while compared to the related arts. These and other objectives of the present invention will become obvious to those of ordinary skill in the art after reading the following detailed description of preferred embodiments. And it is to be understood that both the foregoing general description and the following detailed description are exemplary and are intended to provide further explanation of the invention as claimed.

### BRIEF DESCRIPTION OF THE DRAWINGS

The accompanying drawings are included to provide a further understanding of the invention, and are incorporated in and constitute a part of this specification.

The drawings illustrate embodiments of the invention and, together with the description, serve to explain the principles of the invention. In the drawings:

FIG. 1 shows a schematic diagram of a conventional eye open monitor (EOM) architecture which is applied to a de-serializer circuit in the related art.

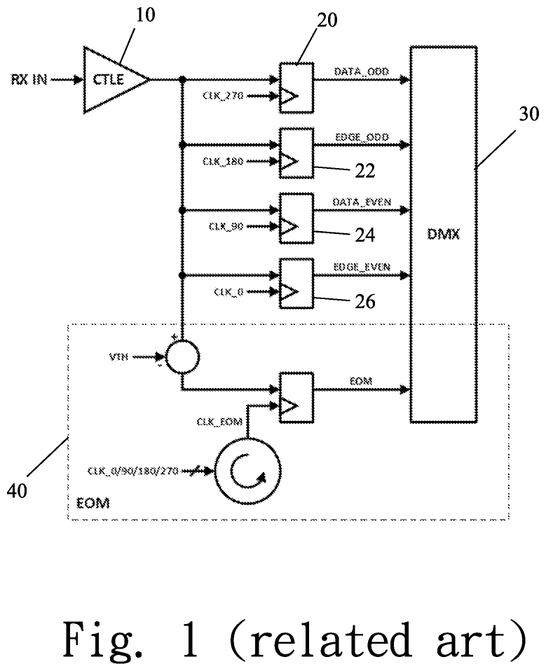

FIG. 2 schematically shows the plurality of different clock signals having various phase, including CLK_0, CLK_90, CLK_180, CLK_270, and the EOM clock CLK_EOM having the extracted same phase as the CLK_0 according to the FIG. 1 architecture.

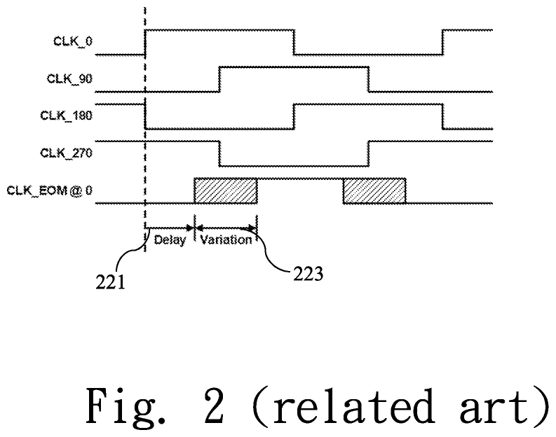

FIG. 3 schematically shows a diagram illustrating an active eye open monitor calibration apparatus being applied to a de-serializer circuit in accordance with one embodiment of the present invention.

FIG. 4 schematically shows a flow chart illustrating a method for active eye open monitor calibration according to the embodiment of the present invention as shown in FIG. 3.

FIG. 5 schematically shows a diagram illustrating the eye open monitor clock signal is sampling the reference clock signal when the calibration selecting signal is given at a low voltage level.

FIG. 6 schematically shows a diagram illustrating the reference clock signal is sampling the eye open monitor clock signal when the calibration selecting signal is given at a high voltage level.

FIG. 7A schematically shows a state machine diagram illustrating the calibration flow of the disclosed active eye open monitor calibration apparatus for retrieving a first phase according to the embodiment of the present invention.

FIG. 7B schematically shows a state machine diagram illustrating the calibration flow of the disclosed active eye open monitor calibration apparatus for subsequently retrieving a second phase and accordingly calculating a final phase according to the embodiment of the present invention.

FIG. 8 shows a demonstrative explanatory example illustrating the calibration selecting signal, the indicator signal and the phase control signal in view of FIG. 7.

### DESCRIPTION OF THE PREFERRED EMBODIMENTS

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express that the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the article “a” and “the” includes the meaning of “one or at least one” of the element or component. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. Every example in the present specification cannot limit the claimed scope of the invention.

In the following descriptions, an active eye open monitor calibration apparatus and a method for active eye open monitor calibration will be provided. The disclosed active eye open monitor calibration apparatus and the disclosed method for active eye open monitor calibration are proposed to avoid phase mismatch occurring in the related arts and achieve optimization of phase synchronization for an eye open monitor clock signal in related to its reference clock signal. Hereinafter, the proposed active eye open monitor calibration apparatus and the proposed method for active eye open monitor calibration are disclosed as being applied to a de-serializer circuit. However, the present invention is certainly not limited thereto. Alternatively, the disclosed technologies regarding the proposed active eye open monitor calibration apparatus and the proposed method for active eye open monitor calibration, as provided below may also be applied to other circuit configurations. And the claim scope of the present invention covers all the equality.

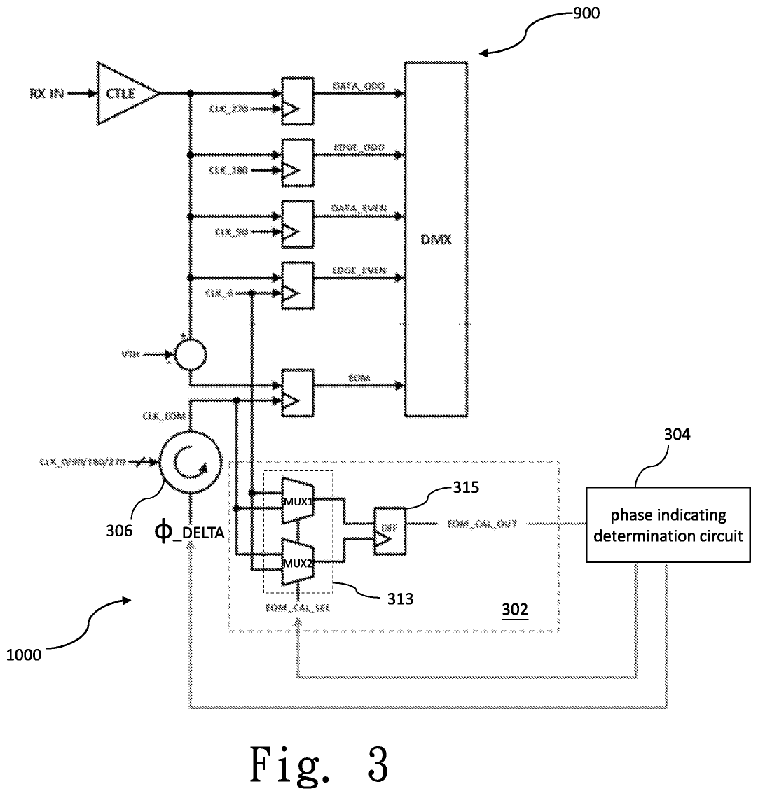

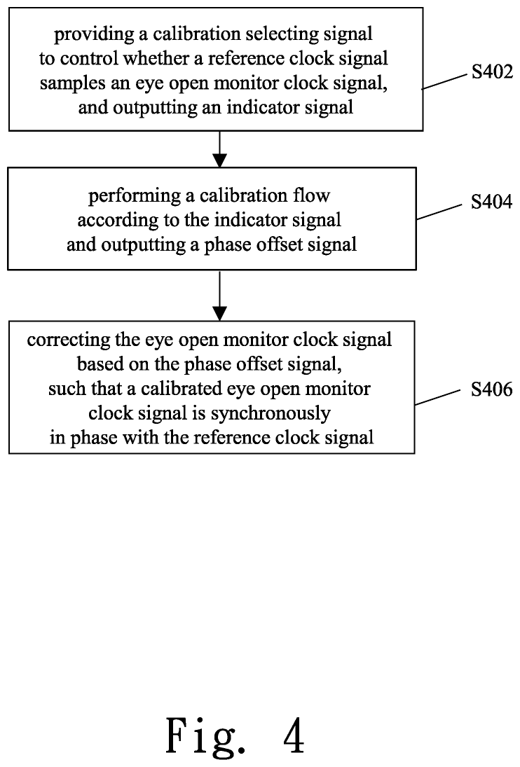

Please refer to FIG. 3 first, which shows a diagram schematically illustrating an active eye open monitor calibration apparatus in accordance with one embodiment of the invention. As illustrated in the embodiment in FIG. 3, the proposed active eye open monitor calibration apparatus 1000 can be, for example, applied to a de-serializer circuit 900 and preciously control the eye open monitor clock signal CLK_EOM have the accurate phase which is synchronous with a phase of its reference clock signal CLK_0/90/180/270. FIG. 4 shows a flow chart illustrating a method for active eye open monitor calibration according to the embodiment of the present invention as shown in FIG. 3. In order to have a better understanding of the technical solution described in the following section, please refer to FIG. 3 accompanying with FIG. 4 for comprehensive teachings of the present invention.

The active eye open monitor calibration apparatus 1000 applicable to a de-serializer circuit 900 is introduced as follows. The active eye open monitor calibration apparatus 1000 includes a phase control circuit 302, a phase indicating determination circuit 304 and a phase correcting circuit 306. According to the embodiment of the present invention, the phase control circuit 302 is provided and operable to receive an eye open monitor clock signal CLK_EOM and a reference clock signal, in which the eye open monitor clock signal CLK_EOM is related to. In such an exemplary embodiment, a clock signal having a phase of 0 degree, illustrated as CLK_0 is taken as an example for describing the technical contents of the present invention.

Nevertheless, the present invention is not limited to such a reference clock signal, as CLK_0. In other alternative and applicable embodiments of the present invention, the reference clock signal may also be operable to have an initial sampling clock phase of 90, 180, 270 degrees, or the like. In general, those skilled in the art and having general knowledge are able to make appropriate modifications or variations with respective to the technical contents disclosed in the present invention without departing from the spirits of the present invention. The present invention is not restricted by the certain limited configurations and/or circuit diagrams disclosed in the embodiments of the present invention. As such, it is believed that the modifications or variations should still fall into the scope of the present invention, and the present invention covers the modifications and its equality.

In general, a calibration selecting signal EOM_CAL_SEL will be provided and input to the phase control circuit 302 for controlling whether the reference clock signal (i.e. the CLK_0) is sampling the eye open monitor clock signal CLK_EOM. In other words, according to the embodiment of the present invention, the reference clock signal CLK_0 and the eye open monitor clock signal CLK_EOM are able to alternately sample each other, and the calibration selecting signal EOM_CAL_SEL is used to control if the reference clock signal CLK_0 samples the eye open monitor clock signal CLK_EOM, or the eye open monitor clock signal CLK_EOM samples the reference clock signal CLK_0. Please refer to the flow chart in FIG. 4 at the same time. As illustrated in the step of S402 in FIG. 4, it can be seen that the calibration selecting signal EOM_CAL_SEL is provided first so as to control whether the reference clock signal CLK_0 samples the eye open monitor clock signal CLK_EOM or the eye open monitor clock signal CLK_EOM samples the reference clock signal CLK_0. After that, the phase control circuit 302 outputs an indicator signal EOM_CAL_OUT, performing as a flag signal indicating the result thereof. And the indicator signal EOM_CAL_OUT will then be received by the phase indicating determination circuit 304.

The phase indicating determination circuit 304 is being electrically connected with the phase control circuit 302 and receiving the indicator signal EOM_CAL_OUT. By such configuration, as illustrated in the step of S404 in FIG. 4, then the phase indicating determination circuit 304 is able to perform a calibration flow according to the received indicator signal EOM_CAL_OUT so as to calculate and output a phase offset signal φ__{DELTA}.

And therefore, the phase correcting circuit 306 which is being electrically connected with the phase indicating determination circuit 304 is operable to receive the phase offset signal φ__{DELTA}, such that the phase correcting circuit 306 modulates and corrects the eye open monitor clock signal CLK_EOM based on the phase offset signal φ__{DELTA}. Subsequently after the eye open monitor clock signal CLK_EOM is corrected based on the phase offset signal φ__{DELTA}, as illustrated in the step of S406 in FIG. 4, it can be obtained that a calibrated eye open monitor clock signal will be synchronously in phase with the reference clock signal (i.e. the CLK_0).

To be more specific, please find the circuit configuration of the disclosed phase control circuit 302 as shown in FIG. 3. According to the embodiment of the present invention, the disclosed phase control circuit 302 may be composed of, and yet not limited to, a data selector circuit 313 and a register circuit 315. And the data selector circuit 313, for instance, includes a first multiplexer MUX1 and a second multiplexer MUX2, which is triggered by the calibration selecting signal EOM_CAL_SEL. According to the embodiment of the present invention, the register circuit 315 which is electrically connected to the first multiplexer MUX1 and the second multiplexer MUX2 is a D flip-flop (DFF) circuit. As a result, after the data selector circuit 313 receives the reference clock signal (i.e. the CLK_0) and the eye open monitor clock signal CLK_EOM and is triggered by the calibration selecting signal EOM_CAL_SEL, a data input and a clock input of the DFF circuit can be switched between the reference clock signal CLK_0 and the eye open monitor clock signal CLK_EOM to control the eye open monitor clock signal CLK_EOM sampling the reference clock signal CLK_0 or the reference clock signal CLK_0 sampling the eye open monitor clock signal CLK_EOM. And the DFF circuit outputs the indicator signal EOM_CAL_OUT to the phase indicating determination circuit 304.

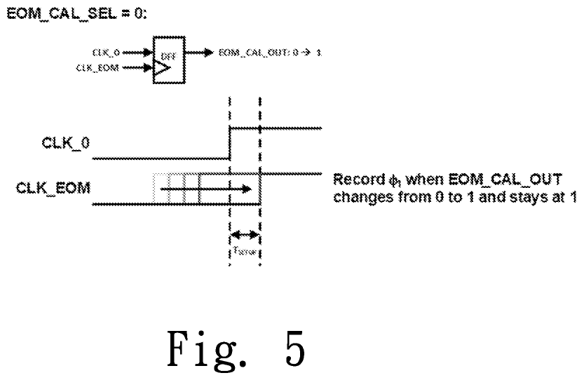

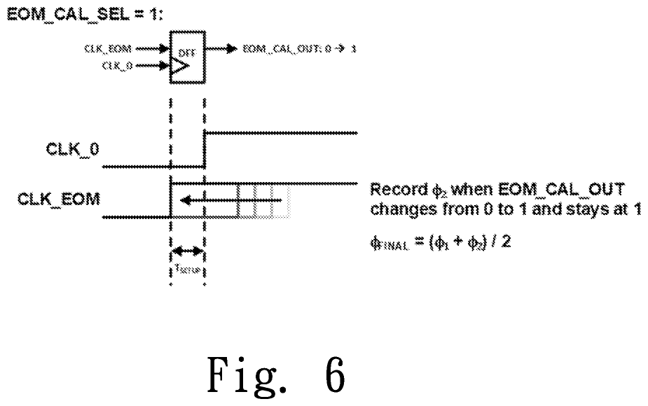

Please refer to FIG. 5 and FIG. 6 which schematically show the diagrams indicating how the calibration selecting signal EOM_CAL_SEL is adopted for determining the alternating switching process between the eye open monitor clock signal CLK_EOM and the reference clock signal CLK_0. As illustrated in FIG. 5, when the calibration selecting signal EOM_CAL_SEL is given at a low voltage level (EOM_CAL_SEL=0), it is determined that the data input of the DFF circuit receives the reference clock signal CLK_0 and the clock input of the DFF circuit receives the eye open monitor clock signal CLK_EOM. Under such a condition, it is obtained that the eye open monitor clock signal CLK_EOM is sampling the reference clock signal CLK_0. As can be seen in FIG. 5, when the indicator signal EOM_CAL_OUT transits from logically low to high and remains stably high (EOM_CAL_OUT=0 to 1 and stays at 1), it is where that the eye open monitor clock signal CLK_EOM is lagging the reference clock signal CLK_0 by a setup time T_{SETUP} of the D flip-flop circuit and as such, a first phase φ₁ will be recorded.

And then, the calibration selecting signal EOM_CAL_SEL is reset as being at a high voltage level (EOM_CAL_SEL=1). As indicated in FIG. 6, when the calibration selecting signal EOM_CAL_SEL is given at a high voltage level (EOM_CAL_SEL=1), it is, on the contrary, that the data input of the DFF circuit receives the eye open monitor clock signal CLK_EOM and the clock input of the DFF circuit receives the reference clock signal CLK_0, such that the reference clock signal CLK_0 is sampling the eye open monitor clock signal CLK_EOM. And when the indicator signal EOM_CAL_OUT transits from logically low to high and remains stably high (EOM_CAL_OUT=0 to 1 and stays at 1), it is where that the eye open monitor clock signal CLK_EOM is leading the reference clock signal CLK_0 by the setup time T_{SETUP} of the D flip-flop circuit. And at this time, a second phase φ₂ will be recorded.

After retrieving the above-mentioned first phase φ₁ and second phase φ₂, a final phase φ_{FINAL} will be calculated as an average phase of the first phase φ₁ and the second phase φ₂ and output as the phase offset signal φ__{DELTA}.

φ_{FINAL}=(φ₁+φ₂)/2

As a result, as indicated by the step S406 in FIG. 4, then the phase correcting circuit 306 receives the phase offset signal φ__{DELTA} and calibrates the eye open monitor clock signal CLK_EOM according to the average phase φ₁+φ₂)/2 so as to correct the eye open monitor clock signal CLK_EOM and to have the calibrated eye open monitor clock signal and its reference clock signal CLK_0 are synchronous in phase.

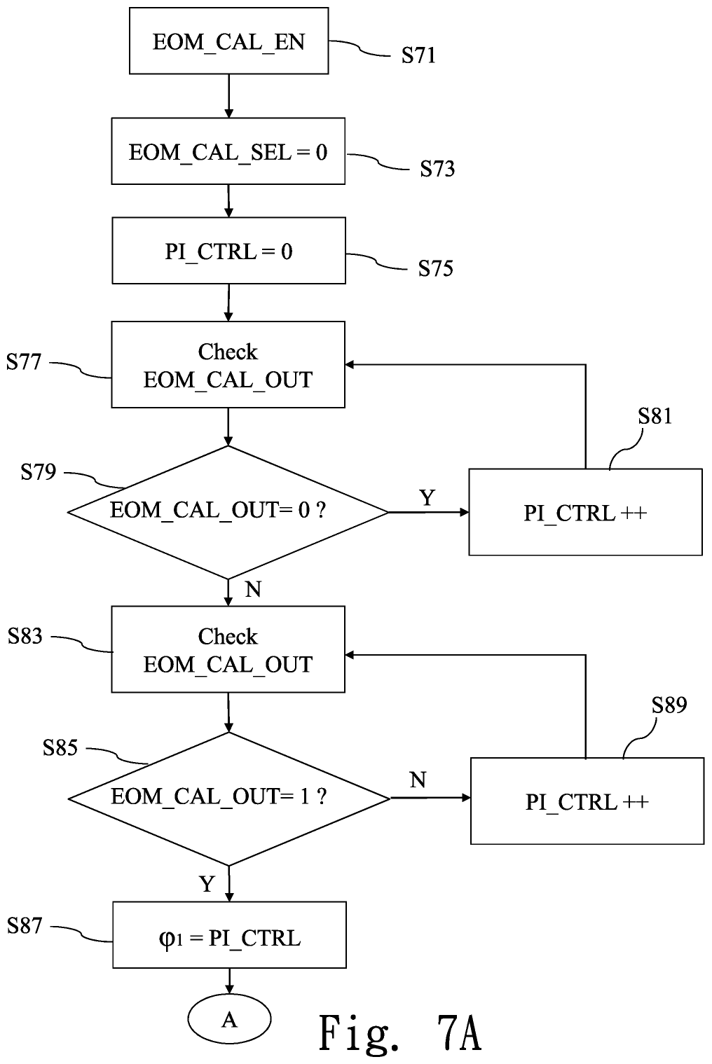

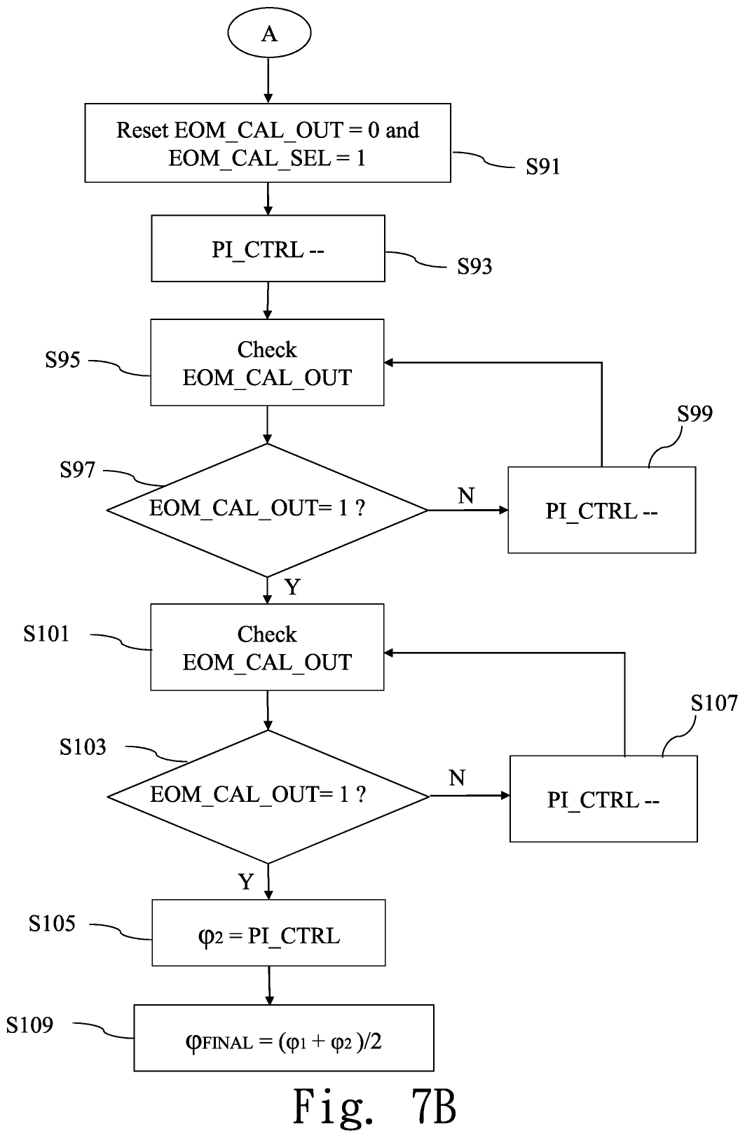

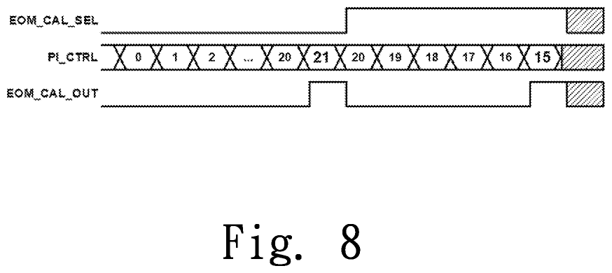

And furthermore, please proceed to refer to FIG. 7A and FIG. 7B, which schematically shows a state machine diagram illustrating the calibration flow of the disclosed active eye open monitor calibration apparatus according to the embodiment of the present invention. And FIG. 8 shows a demonstrative explanatory example in view of FIG. 7. As indicated in the state of S71, the eye open monitor calibration is initially enabled as “EOM_CAL_EN”. After the calibration starts, the calibration selecting signal EOM_CAL_SEL is set to 0 in the state of S73, such that the eye open monitor clock signal CLK_EOM samples the reference clock signal CLK_0. At this time, a phase control signal PI_CTRL starts from 0, as “PI_CTRL=0” in the state of S75. Later, in the state of S77, the present invention is operable to check the indicator signal EOM_CAL_OUT, and in the state of S79, it is examined that if the indicator signal EOM_CAL_OUT is equal to 0 (at a low voltage level).

According to one embodiment of the present invention, if the indicator signal EOM_CAL_OUT is equal to 0, then the phase control signal PI_CTRL increases in order as the indicator signal EOM_CAL_OUT is kept logically low, as illustrated in the state of S81 showing “PI_CTRL++”. Please also find the corresponding figure in FIG. 8 for a better understanding, it can be seen that when the calibration selecting signal EOM_CAL_SEL=0, and the indicator signal EOM_CAL_OUT is kept logically low, the phase control signal PI_CTRL increases by one step each time, 0, 1, 2 . . . 20, such that the phase of the eye open monitor clock signal CLK_EOM moves forward.

Otherwise, if the indicator signal EOM_CAL_OUT is not equal to 0, then in the state of 583, the present invention is operable to check the indicator signal EOM_CAL_OUT again, and in the state of S85, it is examined that if the indicator signal EOM_CAL_OUT is equal to 1. If the indicator signal EOM_CAL_OUT is equal to 1, then in the state of S87, the phase control signal PI_CTRL corresponding to such time point that the indicator signal EOM_CAL_OUT turns from 0 to 1, and is retained at a stable 1, will be recorded as a first phase pi. Otherwise, the state of S89 needs to be performed so as to continually increasing the phase control signal PI_CTRL until in the state of S85: the indicator signal EOM_CAL_OUT turns logically high and is retained stably high for recording the first phase (i₁. Please also refer to the demonstrative drawing in FIG. 8, it is indicated that “PI_CTRL=21” in this case when EOM_CAL_OUT turns from 0 to 1, and is retained at a stable 1. As a result, it is derived that the first phase φ₁ is equal to 21 (φ₁=21) in the state of S87.

After obtaining the first phase φ₁, please refer to FIG. 7B for the following procedures. As can be seen in the state of 591, the indicator signal EOM_CAL_OUT is reset to 0 and the calibration selecting signal EOM_CAL_SEL is set to 1. At this time, it is, on the contrary, for the reference clock signal CLK_0 sampling the eye open monitor clock signal CLK_EOM. As shown in the drawing in FIG. 8, it is illustrated that starting from the above-mentioned first phase φ₁ (φ₁=21), the phase control signal PI_CTRL decreases in order (21, 20, 19, 18 . . . ) as the indicator signal EOM_CAL_OUT is kept logically low. As shown in the state of S93: “PI_CTRL −−”, the phase control signal PI_CTRL decreases by one step each time, 21, 20, 19, 18, 17 . . . , such that the phase of the eye open monitor clock signal CLK_EOM moves backward. And then, in the state of S95, the present invention is operable to check the indicator signal EOM_CAL_OUT, and in the state of S97, it is examined that if the indicator signal EOM_CAL_OUT is equal to 1.

According to one embodiment of the present invention, if the indicator signal EOM_CAL_OUT is not 1, then the phase control signal PI_CTRL continuously decreases in order, as illustrated in the state of S99.

On the other hand, if the indicator signal EOM_CAL_OUT is equal to 1, then in the state of S101, the present invention is operable to check once again the indicator signal EOM_CAL_OUT and determines in the state of S103 if the indicator signal EOM_CAL_OUT is retained stably high as a stable 1. And if so, in the state of S105, the phase control signal PI_CTRL corresponding to the time point that the indicator signal EOM_CAL_OUT turns from 0 to 1, and is retained at a stable 1, will be recorded as a second phase φ₂. Please also find referring to the demonstrative drawing in FIG. 8, it is shown that PI_CTRL=15 in this case when EOM_CAL_OUT turns from 0 to 1, and is retained at a stable 1. As a result, it is derived that the second phase φ₂=15 in the state of S105. Otherwise, if the indicator signal EOM_CAL_OUT is not retained stably high as a stable 1, then the phase control signal PI_CTRL continuously decreases in order as “PI_CTRL −−” in the state of S107 until the indicator signal EOM_CAL_OUT is checked in the state of S101 and examined as a stable 1 in the state of S103 for recording the second phase φ₂ in the state of S105.

As a result, after deriving the above mentioned first phase φ₁ and the second phase φ₂, a final phase φ_{FINAL} can be calculated as an average phase of the first phase φ₁ and the second phase φ₂ and output as the phase offset signal φ__{DELTA} in FIG. 3.

In the state of S109: φ_{FINAL}=(φ₁+φ₂)/2.

According to the demonstrative embodiment of the present invention as shown in FIG. 8, then it is obtained that φ_{FINAL}=(21+15)/2=18. And this is the phase control signal PI_CTRL for the eye open monitor clock signal CLK_EOM to have the exact synchronous phase as the reference clock signal CLK_0. As a result, the eye open monitor clock signal CLK_EOM can be corrected and calibrated based on such phase offset signal φ_{FINAL}=(φ₁+φ₂)/2, such that a calibrated eye open monitor clock signal is synchronously in phase with the reference clock signal. By employing the technical solution provided in the present invention, it is sophisticatedly controlled that the eye open monitor (EOM) clock phase is exactly equal to the reference clock phase, and a phase synchronization is achieved by adopting the active eye open monitor calibration apparatus and the method for active eye open monitor calibration of the present invention.

In addition, it is believed that according to the present invention, such calibration flow as shown in FIG. 7, is allowed to be performed every time before an eye open monitor circuit turns on, in order to avoid phase mismatch due to supply and temperature variation. The proposed active eye open monitor calibration apparatus and the proposed method for active eye open monitor calibration are believed to be effective and advantageous of achieving phase synchronization. In addition, the circuit complexity can be controlled relatively low since a certain standard cell comprising the data selector circuit and the D flip-flop (DFF) circuit is what the present invention simply acquires.

As a result, to sum above, it is apparent that the disclosed active eye open monitor calibration apparatus and the disclosed method for active eye open monitor calibration are illustrated as above when being applied to a de-serializer circuit, however, the present invention is not limited thereto. Other alternative and feasible circuit configuration which may be compatible is preferably practicable and thus the claim scope of the present invention covers the same.

And therefore, based on the at least one embodiment provided above, it is believed that the proposed active eye open monitor calibration apparatus and the proposed method for active eye open monitor calibration of the present invention have been significantly characterized. And an optimal result of phase synchronization for an eye open monitor clock signal in related to its reference clock signal can be accomplished by adopting the present invention. And as a result, when compared to the related arts, it is obvious that the present invention apparently shows much more effective performances than before. In addition, it is believed that the present invention is instinct, effective and highly competitive for IC technology and industries in the market nowadays, whereby having extraordinary availability and competitiveness for future industrial developments and being in condition for early allowance.

It will be apparent to those skilled in the art that various modifications and variations can be made to the present invention without departing from the scope or the spirit of the invention. In view of the foregoing, it is intended that the present invention cover modifications and variations of this invention provided they fall within the scope of the invention and its equivalent.

What is claimed is:

1. An active eye open monitor calibration apparatus, comprising:
a phase control circuit, receiving a reference clock signal and an eye open monitor clock signal, wherein a calibration selecting signal is input to the phase control circuit for controlling whether the reference clock signal is sampling the eye open monitor clock signal, and the phase control circuit outputs an indicator signal;
a phase indicating determination circuit, being electrically connected with the phase control circuit and receiving the indicator signal, wherein the phase indicating determination circuit performs a calibration flow according to the indicator signal so as to calculate and output a phase offset signal; and
a phase correcting circuit, being electrically connected with the phase indicating determination circuit and receiving the phase offset signal, wherein the phase correcting circuit modulates the eye open monitor clock signal based on the phase offset signal, such that a calibrated eye open monitor clock signal is synchronously in phase with the reference clock signal.

2. The active eye open monitor calibration apparatus according to claim 1, wherein the phase control circuit comprises:
a data selector circuit, receiving the reference clock signal and the eye open monitor clock signal and triggered by the calibration selecting signal; and
a register circuit, being electrically connected to the data selector circuit, wherein a data input and a clock input of the register circuit are determined by the calibration selecting signal to switch between the reference clock signal and the eye open monitor clock signal for the register circuit outputting the indicator signal.

3. The active eye open monitor calibration apparatus according to claim 2, wherein the data selector circuit comprises at least one multiplexer triggered by the calibration selecting signal.

4. The active eye open monitor calibration apparatus according to claim 2, wherein the register circuit is a D flip-flop (DFF) circuit.

5. The active eye open monitor calibration apparatus according to claim 2, wherein when the calibration selecting signal is at a low voltage level, the data input of the register circuit receives the reference clock signal and the clock input of the register circuit receives the eye open monitor clock signal, such that the eye open monitor clock signal is sampling the reference clock signal.

6. The active eye open monitor calibration apparatus according to claim 2, wherein when the calibration selecting signal is at a high voltage level, the data input of the register circuit receives the eye open monitor clock signal and the clock input of the register circuit receives the reference clock signal, such that the reference clock signal is sampling the eye open monitor clock signal.

7. The active eye open monitor calibration apparatus according to claim 1, wherein when the eye open monitor clock signal is sampling the reference clock signal, a phase control signal increases in order as the indicator signal is kept logically low, and when the indicator signal turns logically high and is retained stably high, a first phase in related to the phase control signal is recorded.

8. The active eye open monitor calibration apparatus according to claim 7, wherein the indicator signal is reset to logically low, and the calibration selecting signal is switched to have the reference clock signal sampling the eye open monitor clock signal, the phase control signal decreases in order as the indicator signal is kept logically low, and when the indicator signal turns logically high and is retained stably high, a second phase in related to the phase control signal is recorded.

9. The active eye open monitor calibration apparatus according to claim 8, wherein a final phase is calculated as an average phase of the first phase and the second phase and output as the phase offset signal.

10. The active eye open monitor calibration apparatus according to claim 4, wherein when the calibration selecting signal is at a low voltage level and the indicator signal transits from logically low to high and remains high, it is where that the eye open monitor clock signal is lagging the reference clock signal by a setup time of the D flip-flop circuit and a first phase is recorded.

11. The active eye open monitor calibration apparatus according to claim 10, wherein when the calibration selecting signal is at a high voltage level and the indicator signal transits from logically low to high and remains high, it is where that the eye open monitor clock signal is leading the reference clock signal by the setup time of the D flip-flop circuit and a second phase is recorded.

12. The active eye open monitor calibration apparatus according to claim 11, wherein a final phase is calculated as an average phase of the first phase and the second phase and output as the phase offset signal such that the phase correcting circuit calibrates the eye open monitor clock signal according to the average phase so as to have the calibrated eye open monitor clock signal and the reference clock signal are synchronous in phase.

13. The active eye open monitor calibration apparatus according to claim 1, wherein the reference clock signal is operable to have an initial sampling clock phase of 0, 90, 180 or 270 degrees.

14. A method for active eye open monitor calibration, comprising:
providing a calibration selecting signal so as to control whether a reference clock signal is sampling an eye open monitor clock signal, and outputting an indicator signal;
performing a calibration flow according to the indicator signal and outputting a phase offset signal; and
correcting the eye open monitor clock signal based on the phase offset signal, such that a calibrated eye open monitor clock signal is synchronously in phase with the reference clock signal.

15. The method for active eye open monitor calibration according to claim 14, wherein when the calibration selecting signal is at a low voltage level, the eye open monitor clock signal is sampling the reference clock signal.

16. The method for active eye open monitor calibration according to claim 14, wherein when the calibration selecting signal is at a high voltage level, the reference clock signal is sampling the eye open monitor clock signal.

17. The method for active eye open monitor calibration according to claim 15, wherein when the eye open monitor clock signal is sampling the reference clock signal, a phase control signal increases in order as the indicator signal is kept logically low, and when the indicator signal turns logically high and is retained stably high, a first phase in related to the phase control signal is recorded.

18. The method for active eye open monitor calibration according to claim 17, wherein when the indicator signal is reset to logically low, and the calibration selecting signal is switched to a high voltage level such that the reference clock signal is sampling the eye open monitor clock signal, the phase control signal decreases in order as the indicator signal is kept logically low, and when the indicator signal turns logically high and is retained stably high, a second phase in related to the phase control signal is recorded.

19. The method for active eye open monitor calibration according to claim 18, wherein a final phase is calculated as an average phase of the first phase and the second phase and output as the phase offset signal.

20. The method for active eye open monitor calibration according to claim 14, wherein the reference clock signal is operable to have an initial sampling clock phase of 0, 90, 180 or 270 degrees.

21. The method for active eye open monitor calibration according to claim 14, wherein the reference clock signal and the eye open monitor clock signal are received by a data selector circuit and the data selector circuit is triggered by the calibration selecting signal.

22. The method for active eye open monitor calibration according to claim 21, wherein a register circuit is further disposed and electrically connected to the data selector circuit, such that a data input and a clock input of the register circuit are determined by the calibration selecting signal to switch between the reference clock signal and the eye open monitor clock signal for the register circuit outputting the indicator signal.

23. The method for active eye open monitor calibration according to claim 21, wherein the data selector circuit comprises at least one multiplexer triggered by the calibration selecting signal.

24. The method for active eye open monitor calibration according to claim 22, wherein the register circuit is a D flip-flop (DFF) circuit.
